(19) United States
(12) Patent Application Publication
(10) Pub. No.: US 2025/0176260 A1
(43) Pub. Date: May 29, 2025

(54) COMMON DRAIN BIDIRECTIONAL SWITCH

(71) Applicant: Infineon Technologies Canada Inc., OTTAWA (CA)

(72) Inventors: Jayasimha S. PRASAD, Upland, CA (US); Vineet UNNI, Kanata (CA); Thomas William MACELWEE, Nepean (CA); Marco A. ZUNIGA, Berkeley, CA (US)

(21) Appl. No.: 18/522,920

(22) Filed: Nov. 29, 2023

(51) Int. Cl. H01L 27/095; H01L 29/20; H01L 29/40; H01L 29/778; H03K 17/687

(52) U.S. Cl. CPC H10D 84/86; H03K 17/6871; H10D 30/475; H10D 62/8503; H10D 64/112

(57) ABSTRACT

A bidirectional switch for use in high power electronics, being compact and having low on-resistance. The bidirectional switch includes several layers epitaxially grown on a substrate, the epitaxial layer comprising a channel layer and a barrier layer grown on the channel layer, an interface of the barrier layer and the channel layer defining a heterojunction that induces a two-dimensional electron gas (2DEG) within the channel layer, the 2DEG extending laterally at the interface between the barrier and channel layers. The bidirectional switch includes two source contacts, which are ohmic, each in contact with the 2DEG channel layer, but near opposite ends of the 2DEG. The bidirectional switch further includes two gate electrodes disposed over the barrier layer and between the two source contacts. Voltages applied to these gate electrodes controls the current flow in the bidirectional switch between the two contacts.

### BACKGROUND

Electronic circuits typically include transistors, which function as electronic switches that regulate or control current flow in portions of the circuit. One type of transistor is a field-effect transistor in which a voltage is applied to a gate terminal to turn the transistor on and off. A semiconductor channel region is disposed between the drain terminal and the source terminal. When the transistor is on, current flows through the semiconductor channel region between the source terminal and the drain terminal. When the transistor is off, lesser or no current flows through the semiconductor channel region between the source terminal and the drain terminal. The gate terminal is disposed over the semiconductor channel region between the source terminal and the drain terminal. Voltage on the gate terminal generates a field that affects whether the semiconductor channel region conducts current-hence the term “field-effect transistor”.

Silicon has traditionally been used to fabricate transistors. However, wider bandgap semiconductor materials may be used to fabricate transistors that operate at higher voltages and switch higher powers at higher efficiency than silicon transistors. Silicon carbide (SiC), Aluminum Nitride (AlN), Gallium Nitride (GaN) and Zinc Oxide (ZnO) are each examples of wide bandgap semiconductor materials that can be used to fabricate devices for power electronics. One way to use such wider bandgap semiconductor materials is to grow two layers of different semiconductor materials to form a heterojunction.

These two semiconductor materials may have sufficiently different bandgaps such that when brought together, a cusp in the conduction band of the structure lies below the Fermi level just at the top surface of the channel layer. This means that electrons may freely flow within this region. This region is thin in depth and forms a plane parallel to the upper surface of the channel region. Thus, this region is called a “2 DEG” region (two-dimensional electron gas) to emphasize its planar form. Furthermore, this region is also referred to as a 2 DEG “sea of electrons” due to the high mobility of electrons in this region. Thus, the 2 DEG region is highly conductive. The 2 DEG region may forms the channel region of a power semiconductor to allow passage of high currents with relatively low resistance. Field-effect transistors that use such a 2 DEG are referred to as “High-Electron-Mobility Transistors” (or HEMTs).

The subject matter claimed herein is not limited to embodiments that solve any disadvantages or that operate only in environments such as those described above. Rather, this background is only provided to illustrate one example of the technology area where some embodiments described herein may be practiced.

### SUMMARY

Embodiments described herein relate to a bidirectional switch for use in high power electronics. The bidirectional switch is compact in size and has low on-resistance, as will later be explained. The bidirectional switch includes several epitaxial layers grown on a substrate in a specific crystal direction. The epitaxial layer includes a buffer layer, a channel layer and a barrier layer that is epitaxially grown on a substrate. The buffer layer prevents the crystal defects from entering the channel layer. An interface of the barrier layer and the channel layer defines a heterojunction that induces a two-dimensional electron gas (2 DEG) within the channel layer. This 2 DEG extends perpendicular to the epitaxial growth direction.

The bidirectional switch also includes two ohmic contacts, which are each in contact with the 2 DEG of the channel layer, but near opposite ends of the 2 DEG. Thus, the 2 DEG defines a channel of the bidirectional switch through which current may flow from one contact to the other contact, in either direction (hence the term “bidirectional switch”). The bidirectional switch further includes two gate electrodes disposed over the barrier layer and disposed between the two contacts. Voltages applied to these gate electrodes controls whether current flows in the bidirectional switch between the two contacts.

The bidirectional switch may, for example, be considered as two high-electron-mobility transistors (HEMTs) that have their drains connected together. That is, the first of the two ohmic contacts may function as the source contact of the first HEMT, and the most proximate of the two gate electrodes in relation to the first contact may function as the gate electrode of the first HEMT. On the other hand, the second of the two ohmic contacts may function as the source contact of the second HEMT, and the other of the two gate electrodes may function as the gate electrode of the second HEMT. The portion of the 2 DEG between the two gate electrodes may be defined as a common drain region in which the drains of each of the first HEMT and the second HEMT are connected.

Enhancement-mode (E-mode) HEMTs are typically on when a gate-to-source voltage higher than the threshold voltage is applied to its gate, and typically off when less than the gate-to-source threshold voltage is applied to the gate.

In operation of the conventional E-mode HEMT, the voltage at the drain of the HEMT is typically higher than the voltage at the source of the HEMT. In this state, if the gate-to-source voltage is higher than the threshold voltage of the HEMT, current will flow through the 2 DEG from the drain to the source. This may be referred to as the HEMT operating in “forward conduction”. However, gate control of the conduction may be lost if the source voltage is significantly higher than the drain voltage (referred to as “reverse conduction”). This is because the HEMT also has another threshold voltage referred to as the “gate-to-drain threshold voltage” that has no impact in forward conduction but dominates in reverse conduction. That is, because voltages applied to the gate are with respect to the source voltage, and since because the source voltage is significantly higher than the drain voltage, the voltage applied to the gate will be much higher than the gate-to-drain threshold voltage. This means that the HEMT is always on regardless of the control signals applied to the gate. Thus, e the HEMT is always on in reverse conduction mode.

Accordingly, in the bidirectional switch, whichever of the two HEMTs has a higher voltage applied to its source contact (herein referred to as the “upstream HEMT”) will operate in reverse conduction mode and thus be on. On the other hand, the other HEMT with a lower voltage applied to its source contact (herein referred to as the “downstream HEMT”) is capable of its current being controlled by the gate-to-source voltage (forward conduction).

Accordingly, whether current is allowed to flow or is blocked in the bidirectional switch is determined at any given moment by the operation of whichever of the HEMTs is the downstream HEMT at that given moment. That is, if the gate voltage of the downstream HEMT is higher than the threshold voltage, current will flow through the bidirectional switch. On the other hand, if the gate voltage of the downstream HEMT is less than the threshold voltage, current is blocked through the bidirectional switch.

Further, regarding the epitaxial structure of the bidirectional switch, the portion of the 2 DEG between the two gate electrodes functions as a common drain, the overall size of the bidirectional switch may be approximately the same size as a single HEMT. This is because the common drain portion of the 2 DEG is approximately the same length, as the distance between the gate electrode and the drain contact of a single HEMT. This further allows the bidirectional switch to have approximately the same on-resistance as a single HEMT, as the on-resistance of an HEMT is dominated by the distance between the gate electrode and the drain contact of the HEMT. Accordingly, the bidirectional switch, according to the principles described herein, allows for bidirectional switching in high-power applications, while also allowing for the bidirectional switch to have the small on-resistance and compact size of a typical E-mode HEMT.

Additional features and advantages will be set forth in the description which follows, and in part will be obvious from the description, or may be learned by the practice of the teachings herein. Features and advantages of the invention may be realized and obtained by means of the instruments and combinations particularly pointed out in the appended claims. Features of the present invention will become more fully apparent from the following description and appended claims, or may be learned by the practice of the invention as set forth hereinafter.

### BRIEF DESCRIPTION OF THE DRAWINGS

In order to describe the manner in which the advantages and features of the circuits, systems, and methods described herein can be obtained, a more particular description of the embodiments briefly described herein will be rendered by reference to specific embodiments thereof which are illustrated in the appended drawings. Understanding that these drawings depict only typical embodiments of the circuits, systems and methods described herein, and are not therefore considered to be limiting of their scope, certain circuits, systems and methods will be described and explained with additional specificity and detail through the use of the accompanying drawings in which:

FIG. 1 illustrates a cross-sectional view of a bidirectional switch in which the principles described herein may be practiced, and is just one example of a bidirectional switch that is consistent with the principles described herein;

FIG. 2 illustrates a bidirectional switch, which is an example of the bidirectional switch of FIG. 1, but illustrated in circuit structure form;

FIG. 3 illustrates a bidirectional switch, which includes an example of the bidirectional switch of FIG. 2, with the addition of a switching circuit that biases a substrate;

FIG. 4 illustrates a bidirectional switch that represents an example of the bidirectional switch of FIG. 3, but with more detail shown for the switching circuit;

FIG. 5 illustrates a cross-sectional view of a bidirectional switch, which is an example of the bidirectional switch of FIG. 1, but with the inclusion of field plates;

FIG. 6 illustrates a bidirectional switch, which is an example of the bidirectional switch of FIG. 5, but illustrated in circuit structure form with field plate control;

FIG. 7 illustrates a bidirectional switch, which is an example of the bidirectional switch of FIG. 3, but with an example of the switching circuit shown in greater detail;

FIG. 8 illustrates a bidirectional switch, which is an example of the bidirectional switch of FIG. 7, but which shows an even further simplified form of the example switching circuit illustrated in FIG. 7; and

FIG. 9 illustrates a waveform diagrams, which shows an example of signals representing voltages at various locations in the bidirectional switch of FIG. 8.

### DETAILED DESCRIPTION

Embodiments described herein relate to a bidirectional switch for use in high power electronics. The bidirectional switch is compact in size and has low on-resistance, as will later be explained. The bidirectional switch includes several epitaxial layers grown on a substrate in a specific crystal direction. The epitaxial layer includes a buffer layer, a channel layer and a barrier layer that is epitaxially grown on a substrate. The buffer layer prevents the crystal defects from entering the channel layer. An interface of the barrier layer and the channel layer defines a heterojunction that induces a two-dimensional electron gas (2 DEG) within the channel layer. This 2 DEG extends perpendicular to the epitaxial growth direction.

The bidirectional switch also includes two ohmic contacts, which are each in contact with the 2 DEG of the channel layer, but near opposite ends of the 2 DEG. Thus, the 2 DEG defines a channel of the bidirectional switch through which current may flow from one contact to the other contact, in either direction (hence the term “bidirectional switch”). The bidirectional switch further includes two gate electrodes disposed over the barrier layer and disposed between the two contacts. Voltages applied to these gate electrodes controls whether current flows in the bidirectional switch between the two contacts.

The bidirectional switch may, for example, be considered as two high-electron-mobility transistors (HEMTs) that have their drains connected together. That is, the first of the two ohmic contacts may function as the source contact of the first HEMT, and the most proximate of the two gate electrodes in relation to the first contact may function as the gate electrode of the first HEMT. On the other hand, the second of the two ohmic contacts may function as the source contact of the second HEMT, and the other of the two gate electrodes may function as the gate electrode of the second HEMT. The portion of the 2 DEG between the two gate electrodes may be defined as a common drain region in which the drains of each of the first HEMT and the second HEMT are connected.

Enhancement-mode (E-mode) HEMTs are typically on when a gate-to-source voltage higher than the threshold voltage is applied to its gate, and typically off when less than the gate-to-source threshold voltage is applied to the gate.

In operation of the conventional E-mode HEMT, the voltage at the drain of the HEMT is typically higher than the voltage at the source of the HEMT. In this state, if the gate-to-source voltage is higher than the threshold voltage of the HEMT, current will flow through the 2 DEG from the drain to the source. This may be referred to as the HEMT operating in “forward conduction”. However, gate control of the conduction may be lost if the source voltage is significantly higher than the drain voltage (referred to as “reverse conduction”). This is because the HEMT also has another threshold voltage referred to as the “gate-to-drain threshold voltage” that has no impact in forward conduction but dominates in reverse conduction. That is, because voltages applied to the gate are with respect to the source voltage, and since the source voltage is significantly higher than the drain voltage, the voltage applied to the gate will be much higher than the gate-to-drain threshold voltage. This means that the HEMT is always on regardless of the control signals applied to the gate. Thus, e the HEMT is always on in reverse conduction mode.

Accordingly, in the bidirectional switch, whichever of the two HEMTs has a higher voltage applied to its source contact (herein referred to as the “upstream HEMT”) will operate in reverse conduction mode and thus be on. On the other hand, the other HEMT with a lower voltage applied to its source contact (herein referred to as the “downstream HEMT”) is capable of its current being controlled by the gate-to-source voltage (forward conduction).

Accordingly, whether current is allowed to flow or is blocked in the bidirectional switch is determined at any given moment by the operation of whichever of the HEMTs is the downstream HEMT at that given moment. That is, if the gate voltage of the downstream HEMT is higher than the threshold voltage, current will flow through the bidirectional switch. On the other hand, if the gate voltage of the downstream HEMT is less than the threshold voltage, current is blocked through the bidirectional switch.

Further, regarding the epitaxial structure of the bidirectional switch, the portion of the 2 DEG between the two gate electrodes functions as a common drain, the overall size of the bidirectional switch may be approximately the same size as a single HEMT. This is because the common drain portion of the 2 DEG is approximately the same length, as the distance between the gate electrode and the drain contact of a single HEMT. This further allows the bidirectional switch to have approximately the same on-resistance as a single HEMT, as the on-resistance of an HEMT is dominated by the distance between the gate electrode and the drain contact of the HEMT. Accordingly, the bidirectional switch, according to the principles described herein, allows for bidirectional switching in high-power applications, while also allowing for the bidirectional switch to have the small on-resistance and compact size of a typical E-mode HEMT.

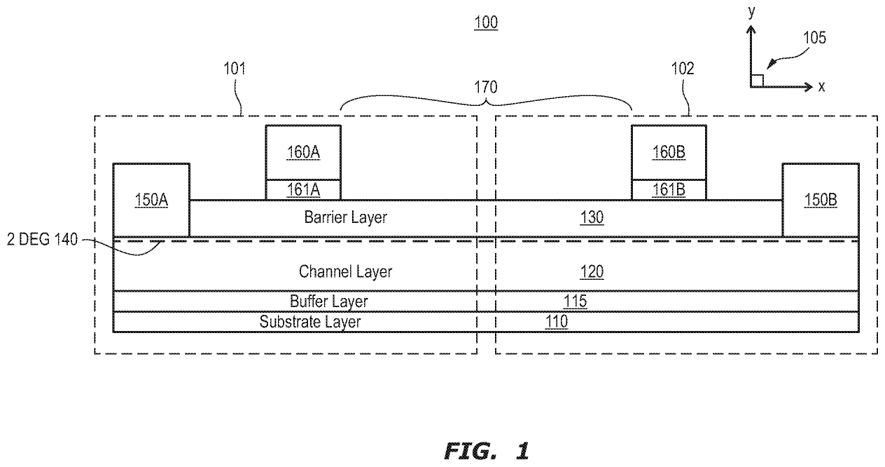

FIG. 1 illustrates a cross-sectional view of a bidirectional switch 100 in which the principles described herein may be practiced, and is just one example of a bidirectional switch that is consistent with the principles described herein. The bidirectional switch 100 includes an epitaxial layer (not labelled) grown on a substrate 110. The epitaxial layer is comprised of a buffer layer 115, a channel layer 120 and a barrier layer 130 epitaxially grown on the channel layer 120.

FIG. 1 also illustrates a coordinate system 105. The y-axis is shown as vertical in FIG. 1. The positive y-direction is the direction in which epitaxial growth occurred to form the buffer layer 115, the channel layer 120 and the barrier layer 130 in sequence. In contrast, the x-axis is horizontal in FIG. 1 and perpendicular to the direction of epitaxial growth. Directions parallel to the y-axis will be referred to as “along” the y-axis. Directions parallel to the x-axis will be referred to as “along” the x-axis.

An interface between the channel layer 120 and the barrier layer 130 defines a heterojunction that induces a two-dimensional electron gas (herein referred to as a “2 DEG”) 140 within the channel layer 120, through which current may flow when the bidirectional switch 100 is on. The 2 DEG 140 extends parallel to the interface between the channel layer 120 and the barrier layer 130 and thus extends along the x-axis. The 2 DEG 140 is formed because the channel layer 120 and the barrier layer 130 are made of different semiconductor materials that have sufficiently different bandgaps such that when connected together, the joined bandgap drops below the Fermi level just within the channel layer 120, thus forming a region (the 2 DEG 140) of high electron concentration. As an example only, if the channel layer 120 is composed of Gallium-Nitride (GaN), and the barrier layer 130 is composed of Aluminum-Gallium-Nitride (AlGaN), the bandgap differences would be sufficient to generate a 2 DEG 140. However, the principles described herein are not limited to the types of semiconductor materials that the channel layer 120 and the barrier layer 130 are composed of.

The bidirectional switch 100 further includes a first contact 150A, a second contact 150B, a first gate electrode 160A and a second gate electrode 160B. The first contact 150A and the second contact 150B are disposed on opposite ends (along the x-axis) of the 2 DEG 140. More specifically, in FIG. 1, the first contact 150A is disposed to electrically connect with the left end of the 2 DEG 140, whereas the second contact 150B is disposed to electrically connect with the right end of the 2 DEG 140.

The first gate electrode 160A and the second gate electrode 160B are disposed over (in the positive y-direction) the barrier layer 130 and are disposed between (along the x-axis) the first contact 150A and the second contact 150B. In FIG. 1, the first gate electrode 160A is more proximate to the first contact 150A, whereas the second gate electrode 160B is more proximate to the second contact 150B. A portion of the 2 DEG 140 below the gate electrode 160A is affected by voltage applied to the gate electrode 160A. Likewise, a portion of the 2 DEG 140 below the gate electrode 160B is affected by voltage applied to the gate electrode 160B. For example, when the bidirectional switch 100 is on, the 2 DEG 140 is continuous below each of the gate electrode 160A and gate electrode 160B, thus allowing current to freely flow between the first contact 150A and the second contact 150B. However, when the bidirectional switch 100 is off, the 2 DEG 140 is discontinuous below either the gate electrode 160A or gate electrode 160B.

The bidirectional switch 100 may, for example, be considered as two enhancement-mode high-electron-mobility transistors (E-mode HEMTs) that have their drains contacts connected together. For instance, the bidirectional switch includes a first HEMT 101 and a second HEMT 102. The first contact 150A is the source contact of the first HEMT 101, and the first gate electrode 160A is the gate electrode of the first HEMT 101. Likewise, the second contact 150B is the source contact of the second HEMT 102, and the second gate electrode 160B is the gate electrode of the second HEMT 102. The portion of the 2 DEG 140 between the first gate electrode 160A and the second contact 160B may be considered as a common drain region 170 in which the drains of each of the first HEMT 101 and the second HEMT 102 are connected.

The first HEMT 101 is an E-mode HEMT because there is a p-doped semiconductor portion 161A between the first gate electrode 160A and the barrier layer 130. Likewise, the second HEMT 102 is another E-mode HEMT because there is another p-doped semiconductor portion 161B between the second gate electrode 160B and the barrier layer 130.

If the drain voltage of the HEMT 101 is higher than the voltage applied to the source contact 150A, and zero voltage is applied to the gate electrode 160A with respect to the source contact 150A, the p-doped semiconductor portion 161A would cause the 2 DEG 140 to be discontinuous under the gate electrode 160A. Likewise, if the drain voltage of the HEMT 102 is higher than the voltage applied to the source contact 150B, and zero voltage is applied to the gate electrode 160B with respect to the source contact 150B, the p-doped semiconductor portion 161B would cause the 2 DEG 140 to be discontinuous under the gate electrode 160B.

In normal operation of a typical HEMT, the drain voltage is more positive than the source voltage. In this state, an E-mode HEMT is on when the gate-to-source voltage is higher than the threshold voltage of the device. Thus, current will flow from drain to source what will be referred to herein as “forward conduction”. Also, if the drain voltage is more positive higher than the source voltage, the E-mode HEMT is off when the gate voltage is less than the threshold voltage of the device.

However, gate control of the current may be different if the source voltage is more positive than the drain voltage (referred to as “reverse conduction”). This is because the HEMT also has another threshold voltage referred to as the “gate-to-drain” threshold voltage that has no impact in forward conduction, but dominates in reverse conduction. That is, because voltages applied to the gate are with respect to the source voltage, and because the source voltage is significantly higher than the drain voltage, the voltage applied to the gate will be much higher than the gate-to-drain threshold voltage. This means that the HEMT is always on regardless of the control signals applied to the gate. Thus, the HEMT is always on in reverse conduction mode.

Accordingly, in the bidirectional switch 100, whichever of the two HEMTs has a higher voltage applied to its source contact (herein referred to as the “upstream HEMT”) will operate in reverse conduction and thus be on. On the other hand, the other HEMT with a lower voltage applied to its source contact (herein referred to as the “downstream HEMT”) is capable of being controlled so as to be off if less than its gate-to-source threshold voltage is applied to its gate electrode, or on (in forward conduction) if at least the gate-to-source threshold voltage is applied to its gate electrode.

Accordingly, whether current is allowed to flow or is blocked in the bidirectional switch 100 is determined at any given moment by the operation of whichever of the HEMTs is the downstream HEMT at that given moment. That is, if the gate voltage of the downstream HEMT is higher than the threshold voltage of the device, current is allowed to flow through the bidirectional switch 100. On the other hand, if the gate voltage of the downstream HEMT has less than the threshold voltage current is blocked from flowing through the bidirectional switch 100.

An example of the operation of the bidirectional switch 100 will now be briefly described in terms of the elements of the bidirectional switch 100. Suppose that the first contact 150A (the source contact of the first HEMT 101) and gate 160A has a high voltage (e.g., positive 100 volts) applied thereto, and that the second contact 150B has a low voltage (e.g., ground) applied thereto. That would mean that the second HEMT 102 is the “downstream HEMT”. Further, suppose that the downstream HEMT 102 is initially off, and thus that the bidirectional switch 100 is off. Recall that the voltage applied to the gate electrode 160A is with respect to the source contact 150A.

In this case, since the gate-to-source voltage is zero volts the gate electrode 160A will still be high (e.g., positive 100 volts). The upstream HEMT then will operate in reverse conduction and its drain 170 at will be at a voltage of 100-Vth, where Vth is the threshold voltage of the device. Similarly, if a gate-to-source positive voltage (e.g., positive 6 volts, higher than Vth) is applied to the gate electrode 160A with respect to the source contact 150A, the gate electrode 160A will also still be high (e.g., positive 106 volts). In this case, since the 2 DEG 140 is formed below the gate 160A, there is continuous 2 DEG from 150A to the drain 170, and the voltage at the drain 170 will be at 100 volts. In either case, when the high voltage is applied to the contact 150A, the gate electrode 160A will also be high compared to the common drain region 170, regardless of the voltage applied to the gate electrode 160A with respect to the contact 150A. Accordingly, when the high voltage is applied to the source contact 150A, the upstream HEMT 101 will surpass its gate-to-drain threshold voltage, the upstream HEMT 101 will operate in reverse conduction, and the voltage at the common drain region 170 will be pulled up to approximately the voltage at the source contact 150A.

However, because the voltage at the common drain region 170 would then be pulled up to be higher than the voltage at the second contact 150B (the source contact of the second HEMT 102), whether the bidirectional switch 100 allows or blocks current flow would then be determined by the operation of the second HEMT (i.e., the downstream HEMT). That is, if a voltage less than Vth is applied to the second gate electrode 160B, the 2 DEG 140 would be discontinuous under the second gate electrode 160B, and the bidirectional switch 100 would block current.

On the other hand, if a voltage higher than the threshold voltage Vth of the second HEMT 102 is applied to the second gate electrode 160B, the 2 DEG 140 would become continuous under the second gate electrode 160B. Thus, the second HEMT 102 would operate in forward conduction, and the bidirectional switch 100 would then instead conduct current from the first contact 150A to the second contact 150B.

The bidirectional switch 100 being “bidirectional”, the operation of the bidirectional switch 100 would be mirrored if the second contact 150B instead had the high voltage applied thereto, and the first contact 150A instead had the low voltage applied thereto.

Further, regarding the epitaxial structure of the bidirectional switch 100, because the portion of the 2 DEG 140 between the two gate electrodes functions as a common drain region 170, the overall size of the bidirectional switch 100 may be practically the same size as (but maybe slightly larger than) a single HEMT. This is because the common drain region 170 is approximately the same length, perpendicular to the epitaxial growth direction, as the distance between the gate electrode and the drain contact of a single HEMT. This further allows the bidirectional switch 100 to have approximately the same on-resistance as a single HEMT, as the on-resistance of an HEMT is dominated by the distance between the gate electrode and the drain contact of the HEMT. Accordingly, the bidirectional switch 100, according to the principles described herein, allows for bidirectional switching in high-power applications, while also allowing for the bidirectional switch to have the small on-resistance and compact size of a typical E-mode HEMT.

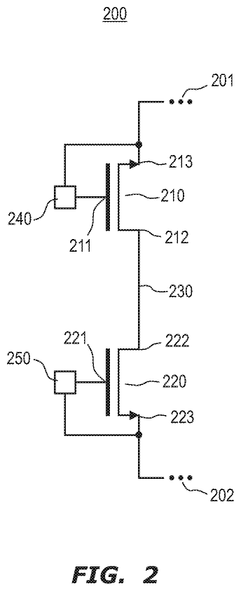

Additional circuit components may be used to assist in the operation of the bidirectional switch 100. To begin to introduce these additional circuit components, FIG. 2 illustrates a bidirectional switch 200, which is an example of the bidirectional switch 100 of FIG. 1, but illustrated in circuit form. That is, the bidirectional switch 200 of FIG. 2 includes a first HEMT 210 and a second HEMT 220. The first HEMT 210 may be an example of the first HEMT 101 of FIG. 1. The second HEMT 220 may be an example of the second HEMT 102 of FIG. 1.

The first HEMT 210 has a gate electrode 211 that controls whether current flows between its drain contact 212 and its source contact 213. Similarly, the second HEMT 220 has a gate electrode 221 that controls whether current flows between its drain contact 222 and its source contact 223. The drain contact 212 of the first HEMT 210 and the drain contact 222 of the second HEMT 220 are connected together to form a common drain 230.

The source contact 213, the source contact 223, the gate electrode 211, the gate electrode 221 and the common drain 230 of FIG. 2 may be respective examples of the first contact 150A, second contact 150B, first gate electrode 160A, second gate electrode 160B and common drain region 170 of FIG. 1. Further, in order to control voltages applied to the gate electrodes 211 and 221, the bidirectional switch 200 also includes gate drivers 240 and 250. Specifically, the gate driver 240 controls voltages applied to the gate electrode 211 of the HEMT 210 with respect to the source contact 213 of the HEMT 210. In addition, the gate driver 250 controls voltages applied to the gate electrode 221 of the HEMT 220 with respect to the source contact 223 of the HEMT 220.

To give a brief example of the operation of the bidirectional switch 200 of FIG. 2, suppose that a high voltage (e.g., positive 100 volts) was applied to the source contact 213 of the first HEMT 210, as represented by ellipses 201. Further, suppose that a low voltage (e.g., ground) was applied to the source contact 223 of the second HEMT 220, as represented by ellipses 202. In this case, the first HEMT 210 would function as the upstream HEMT, and would thus operate in reverse conduction since the voltage at the source contact 213 would be sufficiently higher than the voltage at the common drain 230.

Further, in this case, the second HEMT 220 would function as the downstream HEMT, and would thus be capable of operating in forward conduction if turned on, as the voltage at the common drain 230 would be higher than the voltage at the source contact 223 of the second HEMT 220. Accordingly, if the gate driver 250 applied a gate voltage greater than the threshold voltage of the second HEMT 220 current would be allowed to flow through the bidirectional switch 200 from the source contact 213 of the first HEMT 210 to the source contact 223 of the second HEMT 220. On the other hand, if the gate driver 250 applied a gate voltage less than the threshold voltage of the second HEMT 220, current would be blocked from flowing through the bidirectional switch 200.

Of course, the bidirectional switch 200 being “bidirectional”, the operation of the bidirectional switch 200 would be mirrored if the source contact 223 of the second HEMT 220 instead had the high voltage applied thereto, and the source contact 213 of the first HEMT 210 instead had the low voltage applied thereto. In that case, the second HEMT 220 would function as the upstream HEMT, and the first HEMT 210 would function as the downstream HEMT. That is, current would flow through the bidirectional switch 200 from the source contact 223 of the second HEMT 220 to the source contact 213 of the first HEMT 210 if the gate driver 240 applied a gate voltage higher than the threshold voltage of the first HEMT 210. On the other hand, current would instead be blocked from flowing through the bidirectional switch 200 if the gate driver 240 applied a voltage less than the threshold voltage of the first HEMT 210.

For illustrative purposes only, the example above described the use of the bidirectional switch 200 in the context of one terminal of the bidirectional switch 200 being temporarily fixed at 100 volts, and the other terminal of the bidirectional switch 200 being temporarily fixed at ground. This was merely for keeping the explanation of the operation of the bidirectional switch 200 simple. However, the bidirectional switch will operate for rapidly fluctuating voltages as well. The HEMTs 210 and 220 will simply operate appropriately as upstream and downstream HEMTs as appropriate at any given moment. Thus, the bidirectional switch 200 can be used to switch digital or analog signals.

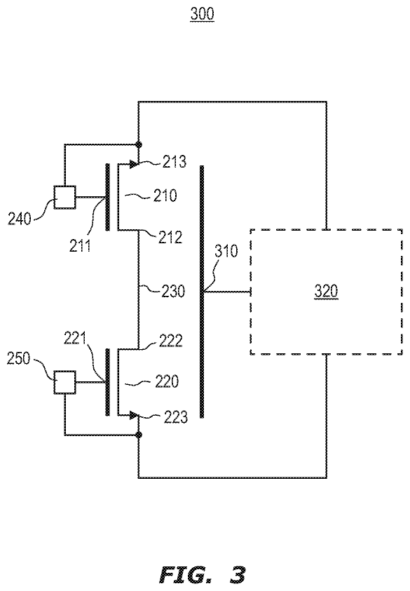

Typically, the source contact of a HEMT is connected to a substrate so that the substrate and the source of a HEMT have the same voltage. However, in the case of the bidirectional switch, the substrate should rather be connected to the source of the downstream HEMT, and not the source of the upstream HEMT. Accordingly, a substrate biasing circuit may be used that actively switches the substrate to be connected to the source of whichever HEMT is the downstream HEMT at any given time. For example, FIG. 3 illustrates a bidirectional switch 300, which includes an example of the bidirectional switch 200 of FIG. 2, with the addition of a switching circuit 320 that biases a substrate 310. As an example, the substrate 310 may be the substrate 110 of FIG. 1. For purposes of explanation, the elements of the bidirectional switch 200 of FIG. 2 are illustrated in FIG. 3 using the same element numbers.

In FIG. 3, the switching circuit 320 is configured to switch to connect the substrate 310 to whichever of the source contacts 213 or 223 has a lower voltage. For example, suppose that the higher voltage is applied to the source contact 213 of the first HEMT 210. In that case, the switching circuit 320 connects the other source contact 223 to the substrate 310. On the other hand, suppose that the higher voltage is applied to the source contact 223 of the second HEMT 220. In that case, the switching circuit 320 connects the other source contact 213 to the substrate 310.

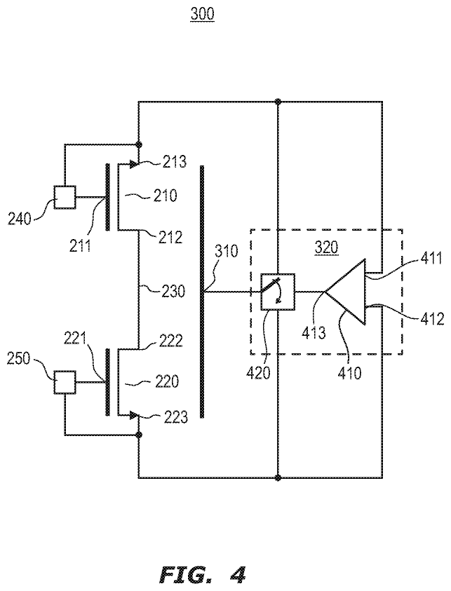

FIG. 4 illustrates a bidirectional switch 400 that represents an example of the bidirectional switch 300 of FIG. 3, but with more detail shown for the switching circuit 320. For purposes of explanation, the elements of the bidirectional switch 300 of FIG. 3 are illustrated in FIG. 4 using the same element numbers. In FIG. 4, the example switching circuit 320 includes a sense amplifier 410 and a switching module 420. The sense amplifier 410 has a first sense amplifier input node 411 connected to the source contact 213 of the first HEMT 210, a second sense amplifier input node 412 connected to the source contact 223 of the second HEMT 220, and a sense amplifier output node 413 connected to the switching module 420. In operation, the sense amplifier 410 senses which of the source contact 213 and source contact 223 has the higher voltage, and outputs a signal that represents the result. Then, depending on the sense amplifier output signal, the switching module 420 then switches to connect the substrate 310 to whichever of the source contact 213 or source contact 223 has the lower voltage.

Accordingly, the sense amplifier 410 and switching module 420 together provide one way by which the substrate can be consistently connected to whichever of the source contact 213 or source contact 223 has the lower voltage applied. Thus, consistent operation of the bidirectional switch may be achieved, regardless of which source contact has the higher or lower voltage applied thereto.

Because the bidirectional switch in accordance with the principles described herein uses HEMTs, the bidirectional switch may be used to control high voltages and currents. Thus, high voltage differences between the source contact of the upstream HEMT and the gate electrode of the downstream HEMT may cause large electric field peaks to be produced in the channel layer on the side of the downstream gate electrode closer to the upstream HEMT drain. Such large electric field peaks may cause the bidirectional switch to degrade quickly over time. Thus, to help reduce the magnitude of the electric field peaks, field plates may be used in the bidirectional switch.

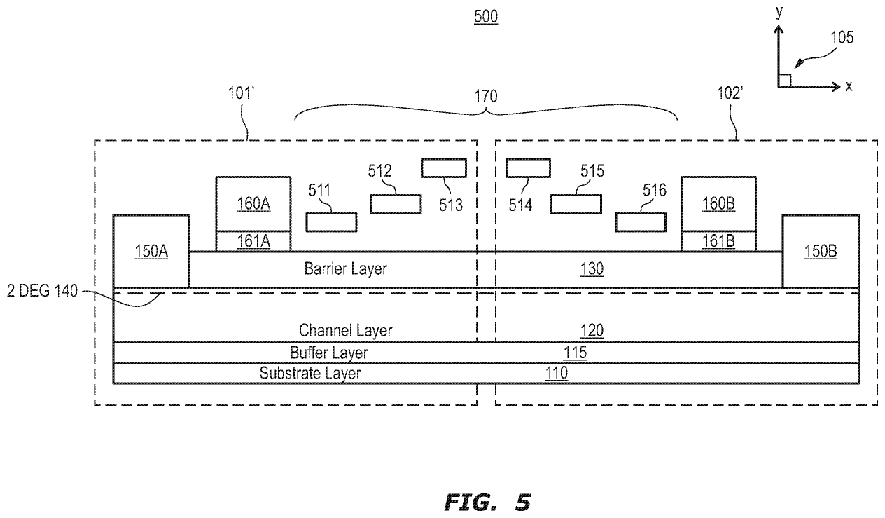

For example, FIG. 5 illustrates a cross-sectional view of a bidirectional switch 500, which is an example of the bidirectional switch 100 of FIG. 1, but with the first HEMT 101 (labelled as 101′ in FIG. 5) including field plates 511 through 513, and with the second HEMT 102 (labelled as 102′ in FIG. 5) including field plates 514 through 516. The remaining elements of the HEMT 101′ are similar to the HEMT 101 of FIG. 1, and thus have the reference numbers as introduced in FIG. 1. Likewise, the remaining elements of the HEMT 102′ are similar to the HEMT 102 of FIG. 1, and thus have the reference numbers as introduced in FIG. 1. In the illustrated embodiment, there are six field plates 511 through 516 in the bi-directional switch 500, but the principles described herein are not limited to the number of field plates included in the bidirectional switch.

The field plates 511 through 516 are each disposed over the barrier layer 130. The field plates 511 through 513 are part of the HEMT 101′, whereas the field plates 514 through 516 are part of the HEMT 102′. As the HEMT 101′ and the HEMT 102′ are symmetrical, mirrored across the center of the common drain region 170, the field plates 511, 512 and 513 are respectively the same in structure and function as the field plates 516, 515 and 514. As a side note, the areas underneath the field plates 511 through 516 may be comprised of a dielectric material that assists in structural stability and electrical isolation between the elements of the bidirectional switch 500.

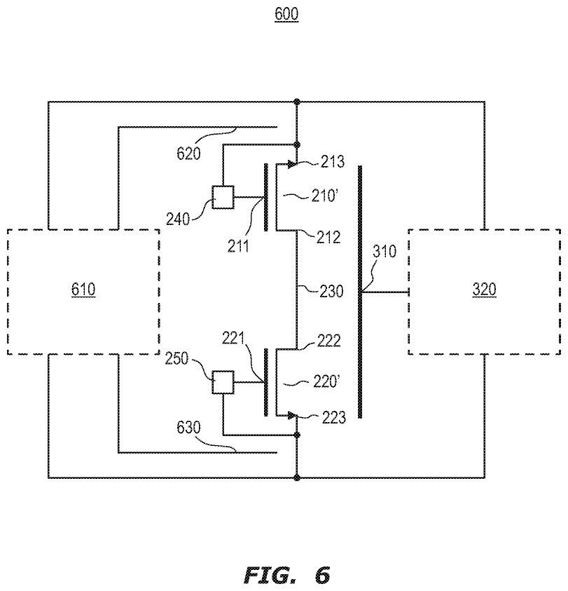

In operation, to help mitigate large electric field peaks at the side of the downstream gate electrode more proximate to the upstream drain region, the field plates for the downstream HEMT may be biased (e.g., with the lower voltage from the source contact of the downstream HEMT), while the field plates for the upstream HEMT are left floating and not biased with any voltage. In order to describe one way of accomplishing this, FIG. 6 will be described in tandem with FIG. 5.

FIG. 6 illustrates a bidirectional switch 600, which is an example of the bidirectional switch 500 of FIG. 5, but illustrated in circuit structure form. The bidirectional switch 600 of FIG. 6 may include, for example, the elements of the bidirectional switch 300 of FIG. 3. As such, for purposes of simplicity, elements of the bidirectional switch 300 of FIG. 3 will be illustrated in the bidirectional switch 600 of FIG. 6 using the same element numbers. However, because the HEMT 101′ and the HEMT 102′ of FIG. 5 include field plates that the HEMT 101 and HEMT 102 of FIG. 1 did not include, the HEMTs in FIG. 6 are labelled HEMT 210′ and HEMT 220′. Particularly, the HEMT 210′ of FIG. 6 is an example of the HEMT 101′ of FIG. 5, whereas the HEMT 220′ of FIG. 6 is an example of the HEMT 102′ of FIG. 5.

The bidirectional switch 600 of FIG. 6 further includes a field plate biasing circuit comprised of a field plate control unit 610, a field plate 620 and a field plate 630. As an example only, the field plate 620 may represent a single field plate, or may represent a group of field plates of the first HEMT 210′ (e.g., the field plates 511 through 513 of the first HEMT 101′ of FIG. 5). Likewise, the field plate 630 may represent a single field plate, or may represent a group of field plates of the second HEMT 220′ (e.g., the field plates 514 through 516 of the second HEMT 102′ of FIG. 5).

In operation, as explained above with respect to FIG. 3, when the higher voltage is applied to the source contact of the upstream HEMT, and the lower voltage is applied to the source contact of the downstream HEMT, the switching circuit 320 connects the substrate 310 to the source contact of the downstream HEMT. Likewise, at approximately the same time, the field plate control unit 610 disconnects the field plate(s) of the upstream HEMT from the source contact of the upstream HEMT, and connects the field plate(s) of the downstream HEMT to the source contact of the downstream HEMT. Thus, the field plate(s) of the downstream HEMT may be biased with the lower voltage from the source contact of the downstream HEMT, thus more effectively mitigating large electric field peaks at the side of the downstream gate electrode more proximate to the upstream source contact.

In some embodiments, the field plate control unit 610 may instead connect the field plate(s) of the downstream HEMT to a different voltage source, such that the field plate(s) of the downstream HEMT may be biased with a voltage other than the lower voltage from the source contact of the downstream HEMT. In one embodiment, the field plate(s) of the downstream HEMT may instead be connected to the gate electrode of the downstream HEMT, such that the field plate(s) receives a bias voltage from that gate electrode. In that case, the field plate most proximate to each gate electrode may be composed of the same material as the p-doped semiconductor portion (e.g., p-doped Gallium-Nitride). In any case, the bidirectional switches of FIG. 5 and FIG. 6 include field plates that may be biased such that electric field peaks are reduced in the channel layer, thus increasing the operating efficiency and longevity of the bidirectional switch.

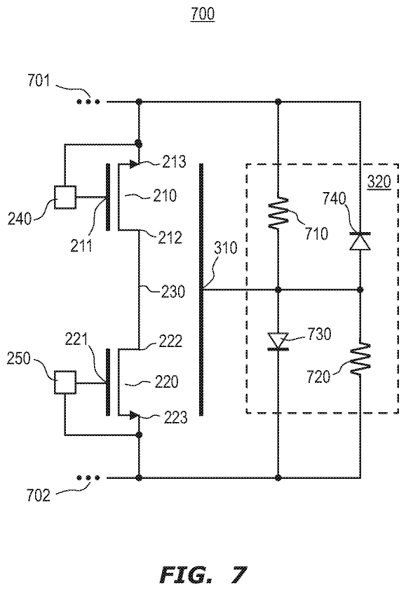

Returning back to the concept of the substrate biasing circuit introduced in FIG. 3, FIG. 7 illustrates another way of connecting the substrate 310 to the source contact of the downstream HEMT. Specifically, FIG. 7 illustrates a bidirectional switch 700, which is an example of the bidirectional switch 300 of FIG. 3, but with an example of the switching circuit 320 shown in greater detail. For purposes of simplicity, the elements of the bidirectional switch 300 of FIG. 3 are illustrated in FIG. 7 using the same element numbers.

In FIG. 7, the example switching circuit 320 includes resistors 710 and 720, as well as diodes 730 and 740. As shown in FIG. 7, the resistor 710 is connected between the substrate 310 and the source contact 213 of the HEMT 210, and the resistor 720 is connected between the substrate 310 and the source contact 223 of the HEMT 220. Each of the resistors 710 and 720 may be very large resistors (e.g., 500 kohms to 1 Meg ohms) that keep the bias current low.

Further, the anodes of the diodes 730 and 740 are connected to the substrate 310, the cathode of the diode 730 is connected to the source contact 223 of the HEMT 220, and the cathode of the diode 740 is connected to the source contact 213 of the HEMT 210. As an example, the diodes 730 and 740 may be fast diodes, such as Schottky diodes (e.g., made of Silicon-Carbide or Gallium-Nitride). Further, for purposes of explanation, suppose that each of the diodes 730 and 740 has a forward bias threshold voltage of approximately 1 volt. Thus, when one of the diodes 730 or 740 is conducting, there may be approximately a 1 volt drop over that diode.

Note that in FIG. 7, while not illustrated, the bidirectional switch 700 may also include field plates and a field plate biasing circuit as described with respect to FIG. 6, as represented in FIG. 7 by ellipses 701 and 702.

To give an example of the operation of the bidirectional switch 700, suppose that the higher voltage is provided to the source contact 213 of the HEMT 210, and that the lower voltage is provided to the source contact 223 of the HEMT 220. In this case, the diode 740 would be reverse biased, and would thus block current from flowing from the source contact 213 to the substrate 310. However, the diode 730 would be forward biased, and current would flow from the substrate 310 through the diode 730 and to the source contact 223 until the voltage of the substrate 310 is close to (within a forward threshold voltage of the diode 730) the voltage at the source contact 223.

On the other hand, suppose that the higher voltage is instead provided to the source contact 223 of the HEMT 220, and that the lower voltage is instead provided to the source contact 213 of the HEMT 210. In this case, the diode 730 would be reverse biased, and the diode 740 would be forward biased, thus causing the voltage of the substrate 310 to be substantially the same as the voltage at the source contact 213. Accordingly, the bidirectional switch 700 of FIG. 7 provides another way by which the substrate 310 may be biased with the voltage present at the source contact of whichever HEMT is the downstream HEMT. In this self-bias circuit, each source of the HEMT sees a low dynamic resistance of the diode 730 or 740.

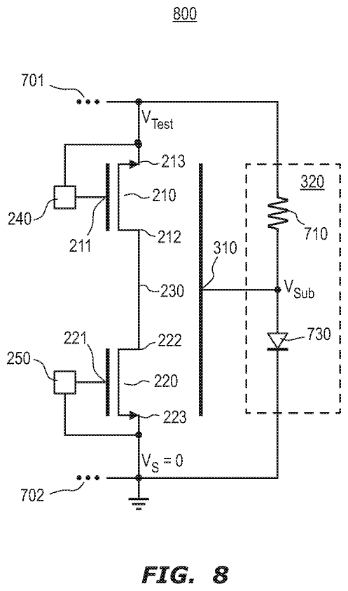

However, the example of the switching circuit 320 illustrated in FIG. 7 may be further simplified. One way of implementing an example of the switching circuit 320 using instead only one resistor and one diode, as is illustrated in FIG. 8. FIG. 8 illustrates a bidirectional switch 800, which is an example of the bidirectional switch 700 of FIG. 7, but with a simplified form. For purposes of explanation, the elements of the bidirectional switch 700 of FIG. 7 are illustrated in FIG. 8 using the same element numbers.

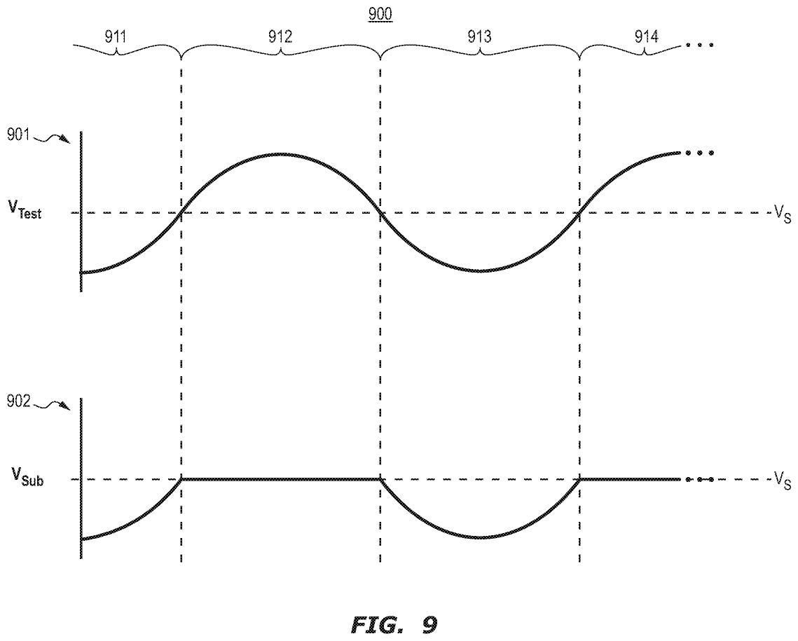

In FIG. 8, the example switching circuit 320 includes only one resistor 710 and one diode 730. The resistor 710 is connected between the substrate 310 and the source contact 213 of the HEMT 210. The anode of the diode 730 is connected to the substrate 310, and the cathode of the diode 730 is connected to the source contact 223 of the HEMT 220. As explained earlier, when source contact 213 is positive with respect to source contact 223, diode 730 conducts and 223 is connected to substrate 310 with one diode drop across it. However, when source contact 223 is positive with respect to source contact 213, the diode 730 is reverse biased and there is no current through resistor 710. Therefore, the source contact 213 and the substrate 310 are almost at the same potential except for a small voltage drop caused due to the leakage current. Under these conditions, source contact 213 sees the resistance of the resistor 710. For purposes of explaining the operation of the bidirectional switch 800, FIG. 9 illustrates a signal chart 900, which shows waveforms a at various locations in the bidirectional switch 800. The signal chart 900 represents the operation of the bidirectional switch 800 when off.

Two signals 901 and 902 are illustrated, which shows the Vtest and Vsub voltage waveforms. The horizontal axis represents time passing from left to right. The vertical axis for each respective signal 901 and 902 represents the amplitude of the signal. The time is divided into four general time periods 911, 912, 913 and 914.

Signal 901 represents a sinusoidal test voltage V_{Test} (in volts) applied to the source contact 213 of the HEMT 210. The source contact 223 of the HEMT 220 is at 0 volts. As seen in FIG. 9, the sinusoidal test voltage V_{Test} oscillates, centered around 0 volts. Thus, in the signal diagrams chart 900, the voltage at the source contact 213 oscillates between being lower than the voltage at the source contact 223 (e.g., during time periods 911 and 913), and being higher than the voltage at the source contact 223 (e.g., during time periods 912 and 914). Accordingly, during time periods 911 and 913, the HEMT 210 is the downstream HEMT and the HEMT 220 is the upstream HEMT. On the other hand, during time periods 912 and 914, the HEMT 220 is the downstream HEMT and the HEMT 210 is the upstream HEMT.

Signal 902 represents the substrate voltage V_{sub} (in volts) at the substrate 310. For purposes of explanation, each of the sinusoidal test voltage V_{Test}, and substrate voltage V_{sub} are labelled in their corresponding locations in FIG. 8.

In time period 911, the sinusoidal test voltage V_{Test} is negative. Thus, the voltage at the source contact 213 is lower than the voltage at the source contact 223, and the HEMT 210 is the downstream HEMT. Also, the upstream HEMT 220 is in reverse conduction. Further, the diode 730 is reverse biased, and current is blocked from flowing from the source contact 223 to the substrate 310. Since the diode 730 is reverse biased, the substrate 310 becomes effectively connected to the source contact 213 of the HEMT 210 via the resistor 710. Thus, during the time period 911, the substrate voltage V_{sub} becomes approximately equal to the sinusoidal test voltage V_{Test} at the source contact 213 of the downstream HEMT 210.

At the beginning of time period 912, the sinusoidal test voltage V_{Test} becomes positive. Thus, the voltage at the source contact 213 is higher than the voltage at the source contact 223, and the HEMT 220 is now the downstream HEMT. Also, the upstream HEMT 210 is in reverse conduction. Further, in this case, the diode 730 is forward biased, and the substrate 310 becomes effectively connected to the source contact 223 of the HEMT 220 via the diode 730. Thus, during time period 912, the substrate voltage V_{Sub} becomes approximately equal to the source voltage Vs at the source contact 223 of the downstream HEMT 220.

At the beginning of the time period 913, the sinusoidal test voltage V_{Test} becomes negative, and the operation is same as described in time period 911. During the time period 914, Vtest becomes positive, and the operation is exactly same as described in time period 912.

Accordingly, the bidirectional switch, according to the principles described herein, allows for bidirectional switching in high-power applications, while also allowing for the bidirectional switch to have the small on-resistance and compact size of a typical E-mode HEMT, such as an E-mode GaN HEMT. Further, the various embodiments of the bidirectional switch described herein allow for consistent substrate biasing, thus allowing for consistent and predictable operation of the bidirectional switch. Finally, the bidirectional switch further allows for biasing of downstream field plates, thus reducing electric field peaks in the channel layer and allowing for reduced device degradation and increased longevity.

### Literal Support Section

Clause 1. A bidirectional switch comprising: several layers epitaxially grown on a substrate in a particular growth direction, the epitaxial layer comprising a channel layer and a barrier layer epitaxially grown on the channel layer, an interface of the barrier layer and the channel layer defining a heterojunction that induces a two-dimensional electron gas (2 DEG) within the channel layer, the 2 DEG extending perpendicular to the epitaxial growth direction; a first contact that is an ohmic contact with a first portion of the 2 DEG; a second contact that is an ohmic contact with a second portion of the 2 DEG; a first gate electrode disposed over the barrier layer, and being disposed between the first contact and the second contact; and a second gate electrode disposed over the barrier layer, and being disposed between the first gate electrode and the second contact, the 2 DEG between the first gate electrode and the second gate electrode defining a common drain region, such that a first high-electron-mobility transistor has the first contact as a source contact, the first gate electrode as a gate electrode, and the common drain region as a drain, and such that a second high-electron-mobility transistor has the second contact as a source contact, the second gate electrode as a gate electrode, and the common drain region as a drain, wherein the bidirectional switch comprises the first high-electron-mobility transistor and the second high-electron-mobility transistor connected in series with the common drain region.

Clause 2. The bidirectional switch according to Clause 1, the bidirectional switch further comprising: a first gate driver configured to control the first high-electron-mobility transistor by applying voltages to the first gate electrode with respect to the first contact; and a second gate driver configured to control the second high-electron-mobility transistor by applying voltages to the second gate electrode with respect to the second contact.

Clause 3. The bidirectional switch according to Clause 1, the bidirectional switch further comprising: a first p-doped semiconductor portion between the first gate electrode and the barrier layer, such that the 2 DEG is discontinuous under the first gate electrode when zero volts is applied to the first gate electrode, such that the first high-electron-mobility transistor is a first enhancement mode high-electron-mobility transistor; and a second p-doped semiconductor portion between the second gate electrode and the barrier layer, such that the 2 DEG is discontinuous under the second gate electrode when zero volts is applied to the second gate electrode, such that the second high-electron-mobility transistor is a second enhancement mode high-electron-mobility transistor.

Clause 4. The bidirectional switch according to Clause 1, the bidirectional switch further comprising a substrate biasing circuit, the substrate biasing circuit comprising: a substrate; and a switching circuit configured to, when the voltage on the first contact is a higher voltage than on the voltage on the second contact, disconnect the substrate from the first contact and connect the substrate to the second contact, the switching circuit further being configured to, when the voltage on the second contact is higher than the voltage on the first contact, disconnect the substrate from the second contact and connect the substrate to the first contact.

Clause 5. The bidirectional switch according to Clause 4, the switching circuit comprising: an sense amplifier having a first input node in conductive contact with the first contact, the sense amplifier further having a second input node in conductive contact with the second contact, the sense amplifier being configured to produce a signal at the output node, the sense amplifier output signal being dependent on voltages present on the first input node of the sense amplifier and the second input node of the sense amplifier; and a switching module that is driven by the sense amplifier output based on the sense amplifier output signal, connect the substrate to either of the first contact of the bidirectional switch or the second contact of the bidirectional switch.

Clause 6. The bidirectional switch according to Clause 1, the bidirectional switch further comprising a field plate biasing circuit, the field plate biasing circuit comprising: a field plate control unit; a first field plate disposed over the barrier layer and the common drain region; and a second field plate disposed over the barrier layer and the common drain region, and being disposed between, perpendicular to the epitaxial growth direction, the first field plate and the second gate electrode.

Clause 7. The bidirectional switch according to Clause 6, further comprising a field plate control unit configured to: when the voltage on the first contact is higher than the voltage on the second contact, disconnect the first field plate from the first contact and connect the second field plate to the second contact, and when the voltage on the first contact lower than the voltage on the second contact, disconnect the second field plate from the second contact and connect the first field plate to the first contact.

Clause 8. The bidirectional switch according to Clause 6, the first field plate being connected to the first gate electrode.

Clause 9. The bidirectional switch according to Clause 8, the first field plate being made of p-doped Gallium-Nitride.

Clause 10. The bidirectional switch according to Clause 6, the bidirectional switch further comprising: a third field plate disposed over, in the epitaxial growth direction, the barrier layer and the common drain region, and being disposed between, perpendicular to the epitaxial growth direction, the first field plate and the second field plate; a fourth field plate disposed over, in the epitaxial growth direction, the barrier layer, and being disposed between, perpendicular to the epitaxial growth direction, the third field plate and the second field plate; a fifth field plate disposed over, in the epitaxial growth direction, the barrier layer, and being disposed between, perpendicular to the epitaxial growth direction, the third field plate and the fourth field plate; and a sixth field plate disposed over, in the epitaxial growth direction, the barrier layer, and being disposed between, perpendicular to the epitaxial growth direction, the fourth field plate and the fifth field plate.

Clause 11. The bidirectional switch according to Clause 10, the distance between the third field plate and the barrier layer in the epitaxial growth direction being greater than the distance between the first field plate and the barrier layer in the epitaxial growth direction, the distance between the fourth field plate and the barrier layer in the epitaxial growth direction being greater than the distance between the second field plate and the barrier layer in the epitaxial growth direction, the distance between the fifth field plate and the barrier layer in the epitaxial growth direction being greater than the distance between the third field plate and the barrier layer in the epitaxial growth direction, and the distance between the sixth field plate and the barrier layer in the epitaxial growth direction being greater than the distance between the fourth field plate and the barrier layer in the epitaxial growth direction.

Clause 12. The bidirectional switch according to Clause 10, the first field plate, the third field plate, and the fifth field plate being electrically connected together, and the second field plate, the fourth field plate, and the sixth field plate being electrically connected together.

Clause 13. The bidirectional switch according to Clause 4, the switching circuit further comprising: a resistor connected between the first contact and the substrate; and a diode having an anode connected to the substrate, the diode further having a cathode connected to the second contact.

Clause 14. The bidirectional switch according to Clause 13, the resistor being a first resistor, the diode being a first diode, the switching circuit further comprising: a second resistor connected between the substrate and the second contact; and a second diode having an anode connected to the substrate, the second diode further having a cathode connected to the first contact.

Clause 15. The bidirectional switch according to Clause 14, the first diode and the second diode each being Silicon-Carbide (SiC) Schottky diodes.

Clause 16. The bidirectional switch according to Clause 14, the first diode and the second diode each being Gallium-Nitride (GaN) diodes.

Clause 17. The bidirectional switch according to Clause 1, the barrier layer being made of Aluminum-Gallium-Nitride (AlGaN), the channel layer being made of Gallium-Nitride (GaN).

Although the subject matter has been described in language specific to structural features and/or methodological acts, it is to be understood that the subject matter defined in the appended claims is not necessarily limited to the described features or acts described above, or the order of the acts described above. Rather, the described features and acts are disclosed as example forms of implementing the claims.

The present disclosure may be embodied in other specific forms without departing from its essential characteristics. The described embodiments are to be considered in all respects only as illustrative and not restrictive. All changes which come within the meaning and range of equivalency of the claims are to be embraced within their scope.

When introducing elements in the appended claims, the articles “a,” “an,” “the,” and “said” are intended to mean there are one or more of the elements. The terms “comprising,” “including,” and “having” are intended to be inclusive and mean that there may be additional elements other than the listed elements.

What is claimed is:

1. A bidirectional switch comprising:
several layers epitaxially grown on a substrate in a particular growth direction, the epitaxial layer comprising a channel layer and a barrier layer epitaxially grown on the channel layer, an interface of the barrier layer and the channel layer defining a heterojunction that induces a two-dimensional electron gas (2 DEG) within the channel layer, the 2 DEG extending perpendicular to the epitaxial growth direction;
a first contact that is an ohmic contact with a first portion of the 2 DEG;
a second contact that is an ohmic contact with a second portion of the 2 DEG;
a first gate electrode disposed over the barrier layer, and being disposed between the first contact and the second contact; and
a second gate electrode disposed over the barrier layer, and being disposed between the first gate electrode and the second contact, the 2 DEG between the first gate electrode and the second gate electrode defining a common drain region,
such that a first high-electron-mobility transistor has the first contact as a source contact, the first gate electrode as a gate electrode, and the common drain region as a drain, and
such that a second high-electron-mobility transistor has the second contact as a source contact, the second gate electrode as a gate electrode, and the common drain region as a drain, wherein the bidirectional switch comprises the first high-electron-mobility transistor and the second high-electron-mobility transistor connected in series with the common drain region.

2. The bidirectional switch according to claim 1, the bidirectional switch further comprising:
a first gate driver configured to control the first high-electron-mobility transistor by applying voltages to the first gate electrode with respect to the first contact; and
a second gate driver configured to control the second high-electron-mobility transistor by applying voltages to the second gate electrode with respect to the second contact.

3. The bidirectional switch according to claim 1, the bidirectional switch further comprising:
a first p-doped semiconductor portion between the first gate electrode and the barrier layer, such that the 2 DEG is discontinuous under the first gate electrode when zero volts is applied to the first gate electrode, such that the first high-electron-mobility transistor is a first enhancement mode high-electron-mobility transistor; and
a second p-doped semiconductor portion between the second gate electrode and the barrier layer, such that the 2 DEG is discontinuous under the second gate electrode when zero volts is applied to the second gate electrode, such that the second high-electron-mobility transistor is a second enhancement mode high-electron-mobility transistor.

4. The bidirectional switch according to claim 1, the bidirectional switch further comprising a substrate biasing circuit, the substrate biasing circuit comprising:
a substrate; and
a switching circuit configured to, when the voltage on the first contact is a higher voltage than on the voltage on the second contact, disconnect the substrate from the first contact and connect the substrate to the second contact,
the switching circuit further being configured to, when the voltage on the second contact is higher than the voltage on the first contact, disconnect the substrate from the second contact and connect the substrate to the first contact.

5. The bidirectional switch according to claim 4, the switching circuit comprising:
an sense amplifier having a first input node in conductive contact with the first contact, the sense amplifier further having a second input node in conductive contact with the second contact, the sense amplifier being configured to produce a signal at the output node, the sense amplifier output signal being dependent on voltages present on the first input node of the sense amplifier and the second input node of the sense amplifier; and
a switching module that is driven by the sense amplifier output based on the sense amplifier output signal, connect the substrate to either of the first contact of the bidirectional switch or the second contact of the bidirectional switch.

6. The bidirectional switch according to claim 1, the bidirectional switch further comprising a field plate biasing circuit, the field plate biasing circuit comprising:
a field plate control unit;
a first field plate disposed over the barrier layer and the common drain region; and
a second field plate disposed over the barrier layer and the common drain region, and being disposed between, perpendicular to the epitaxial growth direction, the first field plate and the second gate electrode.

7. The bidirectional switch according to claim 6, further comprising a field plate control unit configured to:
when the voltage on the first contact is higher than the voltage on the second contact, disconnect the first field plate from the first contact and connect the second field plate to the second contact, and
when the voltage on the first contact lower than the voltage on the second contact, disconnect the second field plate from the second contact and connect the first field plate to the first contact.

8. The bidirectional switch according to claim 6, the first field plate being connected to the first gate electrode.

9. The bidirectional switch according to claim 8, the first field plate being made of p-doped Gallium-Nitride.

10. The bidirectional switch according to claim 6, the bidirectional switch further comprising:
a third field plate disposed over, in the epitaxial growth direction, the barrier layer and the common drain region, and being disposed between, perpendicular to the epitaxial growth direction, the first field plate and the second field plate;
a fourth field plate disposed over, in the epitaxial growth direction, the barrier layer, and being disposed between, perpendicular to the epitaxial growth direction, the third field plate and the second field plate;
a fifth field plate disposed over, in the epitaxial growth direction, the barrier layer, and being disposed between, perpendicular to the epitaxial growth direction, the third field plate and the fourth field plate; and
a sixth field plate disposed over, in the epitaxial growth direction, the barrier layer, and being disposed between, perpendicular to the epitaxial growth direction, the fourth field plate and the fifth field plate.

11. The bidirectional switch according to claim 10,
the distance between the third field plate and the barrier layer in the epitaxial growth direction being greater than the distance between the first field plate and the barrier layer in the epitaxial growth direction,
the distance between the fourth field plate and the barrier layer in the epitaxial growth direction being greater than the distance between the second field plate and the barrier layer in the epitaxial growth direction,
the distance between the fifth field plate and the barrier layer in the epitaxial growth direction being greater than the distance between the third field plate and the barrier layer in the epitaxial growth direction, and
the distance between the sixth field plate and the barrier layer in the epitaxial growth direction being greater than the distance between the fourth field plate and the barrier layer in the epitaxial growth direction.

12. The bidirectional switch according to claim 10,
the first field plate, the third field plate, and the fifth field plate being electrically connected together, and
the second field plate, the fourth field plate, and the sixth field plate being electrically connected together.

13. The bidirectional switch according to claim 4, the switching circuit further comprising:
a resistor connected between the first contact and the substrate; and
a diode having an anode connected to the substrate, the diode further having a cathode connected to the second contact.

14. The bidirectional switch according to claim 13, the resistor being a first resistor, the diode being a first diode, the switching circuit further comprising:
a second resistor connected between the substrate and the second contact; and
a second diode having an anode connected to the substrate, the second diode further having a cathode connected to the first contact.

15. The bidirectional switch according to claim 14, the first diode and the second diode each being Silicon-Carbide (SiC) Schottky diodes.

16. The bidirectional switch according to claim 14, the first diode and the second diode each being Gallium-Nitride (GaN) diodes.

17. The bidirectional switch according to claim 1, the barrier layer being made of Aluminum-Gallium-Nitride (AlGaN), the channel layer being made of Gallium-Nitride (GaN).
